(19) United States
(12) Patent Application Publication
(10) Pub. No.: US 2026/0190539 A1
(43) Pub. Date: Jul. 2, 2026

(54) SELF-POWERED BROADBAND PHOTO-DETECTING DEVICE AND METHOD OF FABRICATING THE SAME

(71) Applicant: Ming Chi University of Technology, New Taipei City (TW)

(72) Inventors: Sheng-Chi CHEN, New Taipei City (TW); Kumar MAHESH, New Taipei City (TW); Saravanan ADHIMOORTHY, New Taipei City (TW); Bohr-Ran HUANG, New Taipei City (TW); Hui SUN, New Taipei City (TW)

(21) Appl. No.: 19/090,254

(22) Filed: Mar. 25, 2025

(30) Foreign Application Priority Data
Dec. 27, 2024 (TW) 113151284

(51) Int. Cl. H10F 77/40; B82Y 15/00; B82Y 20/00; B82Y 40/00; H10F 30/21; H10F 30/222

(52) U.S. Cl. CPC H10F 77/413; B82Y 15/00; B82Y 20/00; B82Y 40/00; H10F 30/222; H10F 30/288

(57) ABSTRACT

The invention discloses a self-powered broadband photo-detecting device and a fabricating method. According to the invention, the self-powered broadband photo-detecting device includes a substrate, a plurality of nanorods, and a plurality of nanoflake clusters. The plurality of nanorods is formed on the upper surface of the substrate. The plurality of nanorods is formed from an oxide of a metal. Each nanoflake cluster is formed on a respective top of one of the plurality of nanorods. The plurality of nanoflake clusters is formed of a chalcogenide of the metal.

### CROSS-REFERENCE TO RELATED APPLICATION

This utility application claims priority to Taiwan Application Serial Number 113151284, filed Dec. 27, 2024, which is incorporated herein by reference.

### BACKGROUND OF THE INVENTION

### 1. Field of the Invention

The invention relates to a self-powered broadband photo-detecting device and a method of fabricating the same, and more particularly, to a self-powered broadband photo-detecting device integrating one-dimensional and two-dimensional nanostructures, utilizing a metal chalcogenide and having excellent performances, as well as a method of fabricating the same.

### 2. Description of the Prior Art

Recently, it has been demonstrated that the performance of photodetectors (PDs) can be significantly enhanced by utilizing the light-induced pyroelectric effect, a phenomenon commonly referred to as the pyro-phototronic effect (PPE). In this effect, the illumination-induced temperature gradient generates a pyroelectric potential across the photodetector (PD) material. When coupled with the heterostructure built-in potential, this potential modulates the transport of charges across the device. In the context of pyroelectric semiconductors, pyroelectric polarization can be induced by altering the temperature gradient across the material over time.

Numerous studies have investigated PDs leveraging the PPE. Zhaona Wang et al. spearheaded research into a ZnO/perovskite heterojunction-based PD, demonstrating notable enhancements in PD performance through the utilization of the light-induced PPE in ZnO nanowires. Integration of the PPE led to a remarkable increase of 322% in both detectivity and responsivity, particularly under UV illumination. Similarly, Zhaona Wang et al. study on p-Si/n-ZnO heterojunction-based PDs showcased significant performance improvements attributed to the light-induced PPE, resulting in a remarkable enhancement of 599 % in responsivity under UV illumination. Jihong Liu et al. explored a Cu(In, Ga)Se₂ multilayer heterojunction-based PD, unveiling synergistic mechanisms that yielded remarkable enhancements of 505.5% in responsivity and 519.4 % in detectivity, particularly under 808 nm illumination. Jihong Liu et al. investigated a Cu(In, Ga)Se₂ multilayer heterojunction, demonstrating high-sensitivity flexible position sensing tuned by the piezo-pyroelectric effect under 405-1064 nm illumination. Xuemei Zheng et al. investigated an Au-decorated PbI₂/ZnO heterojunction, demonstrating improved PD performance attributed to incorporating the PPE, albeit limited to the UV detection range. While certain single-layered PPE-based PDs exhibit high performance, they are plagued by limitations such as restricted spectral detection ranges, performance issues, and cost constraints.

In addition, due to the high specific surface area and unique superior properties of low-dimensional materials, particularly one-dimensional nanorods and two-dimensional nanoflakes, these materials play a crucial role in pursuing higher performance for broadband PDs. Metal chalcogenides have garnered increasing attention from researchers due to their distinctive properties and diverse application fields, including higher electron mobility, excellent chemical stability, and potential use in sensors, energy storage devices, supercapacitors, and lithium-ion batteries. However, there has yet to be a proposal to integrate these nanostructures and materials technologies to enhance the optoelectronic performance of broadband photo-detecting devices significantly.

### SUMMARY OF THE INVENTION

Accordingly, one scope of the invention is to provide a self-powered broadband photo-detecting device integrating one-dimensional and two-dimensional nanostructures, utilizing a metal chalcogenide and having excellent performances and a method of fabricating the same.

A self-powered broadband photo-detecting device, according to a preferred embodiment of the invention, includes a substrate, a plurality of nanorods, and a plurality of nanoflake clusters. The substrate has an upper surface. The plurality of nanorods is formed on the upper surface of the substrate. The plurality of nanorods is formed of an oxide of a designated metal. The designated metal can be tin, alumina, lead, arsenic, plutonium, phosphorus, antimony, boron, aluminum, gallium, plutonium, titanium, sodium, etc. Each nanoflake cluster is formed on a respective top of one of the plurality of nanorods. The plurality of nanoflake clusters is formed of a chalcogenide of the designated metal.

In one embodiment, a chalcogen in the chalcogenide can be sulfur, selenium, tellurium, hydrazine, livermorium, etc.

In one embodiment, the substrate can be formed of glass, metal, ceramic, polymer, semiconductor, etc.

A method, according to a preferred embodiment of the invention, of fabricating a self-powered broadband photo-detecting device is to prepare a substrate. The substrate has an upper surface. Then, the method, according to the invention's preferred embodiment, is, by a first hydrothermal process, to form a plurality of nanorods on the upper surface of the substrate. The plurality of nanorods is formed of an oxide of a designated metal. The designated metal can be tin, alumina, lead, arsenic, plutonium, phosphorus, antimony, boron, aluminum, gallium, plutonium, titanium, sodium, etc. Finally, according to the invention's preferred embodiment, the method is to form a plurality of nanoflake clusters by a second hydrothermal process. Each nanoflake cluster is formed on a respective top of one of the plurality of nanorods. The plurality of nanoflake clusters is formed of a chalcogenide of the designated metal

Distinguishable from the prior arts, the self-powered broadband photo-detecting device, according to the invention, integrates one-dimensional and two-dimensional nanostructures, utilizes a metal chalcogenide, and has excellent performances. According to the invention, the self-powered broadband photo-detecting device is conducive to commercialization.

The advantage and spirit of the invention may be understood by the following recitations and the appended drawings.

### BRIEF DESCRIPTION OF THE APPENDED DRAWINGS

FIG. 1 is a schematic diagram of the appearance of a self-powered broadband photo-detecting device according to the preferred embodiment of the invention.

FIGS. 2 and 3 are perspective views of the structures obtained at each stage of a method, according to the preferred embodiment of the invention of fabricating the self-powered broadband photo-detecting device as shown in FIG. 1.

FIG. 4 shows a field emission scanning electron microscope (FESEM) photograph of the SnO₂ nanorods as an example of the invention.

FIG. 5 shows a FESEM photograph of the SnO₂/SnS₂ heterostructure of the example of the invention.

FIG. 6 shows the X-ray Diffraction (XRD) spectra of SnO₂ and SnO₂/SnS₂ of the example of the invention formed on a p-type silicon substrate.

FIG. 7 shows the current-voltage (I-V) characteristics of the p-Si/SnO₂/SnS₂ heterostructure of the example of the invention under illumination with light sources of different wavelengths and maintaining a constant illumination intensity of 2 mW/cm².

FIG. 8 shows the I-V characteristics of p-Si/SnO₂ nanorods of control under illumination with light sources of different wavelengths and maintaining a constant illumination intensity of 2 mW/cm².

FIG. 9 shows the I-V characteristics of p-Si/SnS₂ nanoflakes of another control under illumination with light sources of different wavelengths and maintaining a constant illumination intensity of 2 mW/cm².

FIG. 10 shows the current-time (I-t) characteristics of the p-Si/SnO₂/SnS₂ heterostructure of the example of the invention under illumination with a light source of 365 nm wavelength and different illumination intensities.

FIG. 11 shows the I-t characteristics of the p-Si/SnO₂/SnS₂ heterostructure of the example of the invention under illumination with a light source of 456 nm wavelength and different illumination intensities.

FIG. 12 shows the I-t characteristics of the p-Si/SnO₂/SnS₂ heterostructure of the example of the invention under illumination with a light source of 532 nm wavelength and different illumination intensities.

FIG. 13 shows the I-t characteristics of the p-Si/SnO₂/SnS₂ heterostructure of the example of the invention under illumination with a light source of 632 nm wavelength and different illumination intensities.

FIG. 14 shows the I-t characteristics of the p-Si/SnO₂/SnS₂ heterostructure of the example of the invention under illumination with a light source of 850 nm wavelength and different illumination intensities.

FIG. 15 is the I-t characteristics of the p-Si/SnO₂ nanorods of the control under illumination with light sources of different wavelengths and maintaining a constant illumination intensity of 2 mW/cm².

FIG. 16 is the I-t characteristics of the p-Si/SnS₂ nanoflakes of another control under illumination with light sources of different wavelengths and maintaining a constant illumination intensity of 2 mW/cm².

### DETAILED DESCRIPTION OF THE INVENTION

Some preferred embodiments and practical applications of this present invention will be explained in the following paragraph, describing the characteristics, spirit, and advantages.

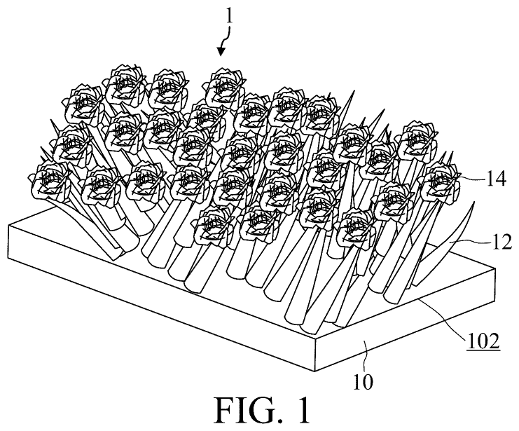

Referring to FIG. 1, FIG. 1 schematically illustrates a self-powered broadband photo-detecting device 1 according to the invention's preferred embodiment with a perspective view.

As shown in FIG. 1, the self-powered broadband photo-detecting device 1, according to the preferred embodiment of the invention, includes a substrate 10, a plurality of nanorods 12, and a plurality of nanoflake clusters 14.

The Substrate 10 has an upper surface of 102. In one embodiment, substrate 10 can be formed of a glass, a metal, a ceramic, a polymer, a semiconductor, and so on. For example, substrate 10 can be formed using polyetheretherketone (PEEK) for polymer materials.

The plurality of nanorods 12 is formed on the upper surface 102 of the substrate 10. The plurality of nanorods 12 is formed of an oxide of a designated metal. In particular, the designated metal can be tin, alumina, lead, arsenic, plutonium, phosphorus, antimony, boron, aluminum, gallium, plutonium, titanium, sodium, and so on.

Each nanoflake cluster 14 is formed on a respective top of one of the plurality of nanorods 12. In particular, the plurality of nanoflake clusters 14 is formed of a chalcogenide of the designated metal.

In one embodiment, a chalcogen in the chalcogenide can be sulfur, selenium, tellurium, hydrazine, livermorium, etc.

In one embodiment, under illumination with a light source of 850 nm wavelength, a responsivity of the self-powered broadband photo-detecting device 1, according to the preferred embodiment of the invention, is equal to or greater than 2.6 mA/W

Referring to FIG. 2 through FIG. 3 and FIG. 1 illustrate a method, according to the preferred embodiment of the invention, of fabricating the self-powered broadband photo-detecting device 1 as shown in FIG. 1 with perspective views.

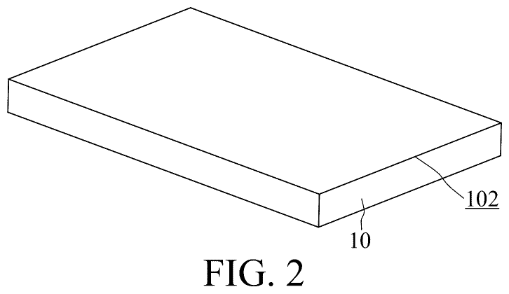

As shown in FIG. 2, the method according to a preferred embodiment of the invention is to prepare a substrate 10. Substrate 10 has an upper surface of 102. Substrate 10 has an upper surface of 102. In one embodiment, substrate 10 can be formed of a glass, a metal, a ceramic, a polymer, a semiconductor, and so on. For example, substrate 10 can be formed using polyetheretherketone (PEEK) for polymer materials.

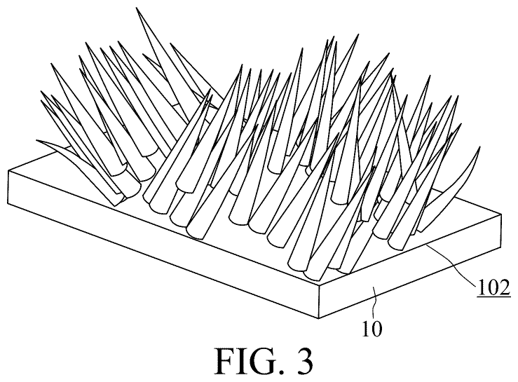

As shown in FIG. 3, according to the invention's preferred embodiment, the method is to form a plurality of nanorods 12 on the upper surface 102 of substrate 10 by a first hydrothermal process. The plurality of nanorods 12 is formed of an oxide of a designated metal. In particular, the designated metal can be tin, alumina, lead, arsenic, plutonium, phosphorus, antimony, boron, aluminum, gallium, plutonium, titanium, sodium, and so on.

Finally, the method according to the preferred embodiment of the invention is, by a second hydrothermal process, to form a plurality of nanoflake clusters 14 to finish the self-powered broadband photo-detecting device 1 according to the invention as shown in FIG. 1. Each nanoflake cluster 14 is formed on a respective top of one of the plurality of nanorods 12. In particular, the plurality of nanoflake clusters 14 is formed of a chalcogenide of the designated metal

In one embodiment, a chalcogen in the chalcogenide can be sulfur, selenium, tellurium, hydrazine, livermorium, etc.

In one embodiment, under illumination with a light source of 850 nm wavelength, a responsivity of the self-powered broadband photo-detecting device 1, according to the preferred embodiment of the invention, is equal to or greater than 2.6 mA/W

In one example, according to the method of the invention, a plurality of SnO₂ nanorods are formed on the upper surface of a p-type silicon substrate by a first hydrothermal process. In this example, 1.107 g of SnCl₄·5H₂O and 0.9 g of NaOH are added to 40 mL of deionized water and stirred with a magnetic stirrer for 30 minutes until both chemicals completely dissolve. Subsequently, the p-type silicon substrate and the abovementioned solution are placed into a 100 mL stainless steel autoclave with a Teflon liner, which is then sealed and heated inside a mechanical convection oven at 100° C. for 72 h. After cooling the system, the resulting substrate material is dried in ambient air at 50° C. for 13 hours.

Next, in this example, SnS₂ nanoflake clusters are synthesized on the abovementioned structure by a second hydrothermal process. In this example, 0.3793 g of thiourea (CH₄N₂S) and 1.2126 g of stannic chloride pentahydrate (SnCl₄·5H₂O) are stirred in 40 mL of deionized water for one hour to ensure uniform dispersion. The resulting mixture is then transferred to a Teflon container, sealed in a stainless steel autoclave, and subjected to hydrothermal treatment at 200° C. for 24 hours. After the system is cooled, the final product is allowed to stand at room temperature for 12 hours and is repeatedly washed with water and ethanol. Subsequently, the mixture is dripped onto the Si/SnO₂ nanorods using a micropipette (range 0˜1000 μL) and placed on a hot plate at 60° C. for 12 hours. Then, platinum is sputtered onto the SnS₂/SnO₂ as the top electrode, while Ag is coated on the bottom surface of the p-type silicon substrate as the bottom electrode for testing the optoelectronic characteristics.

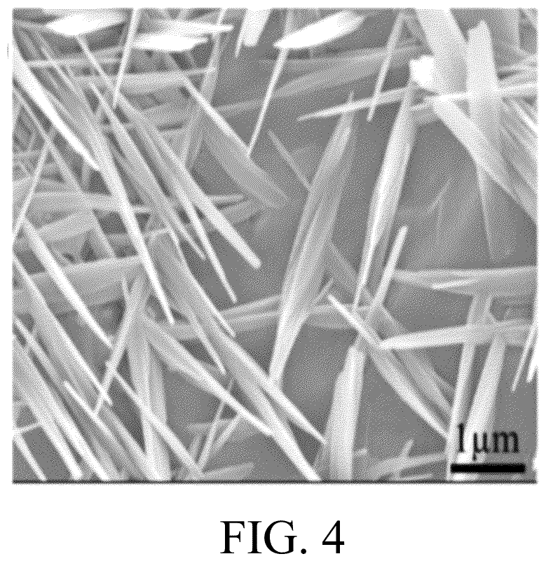

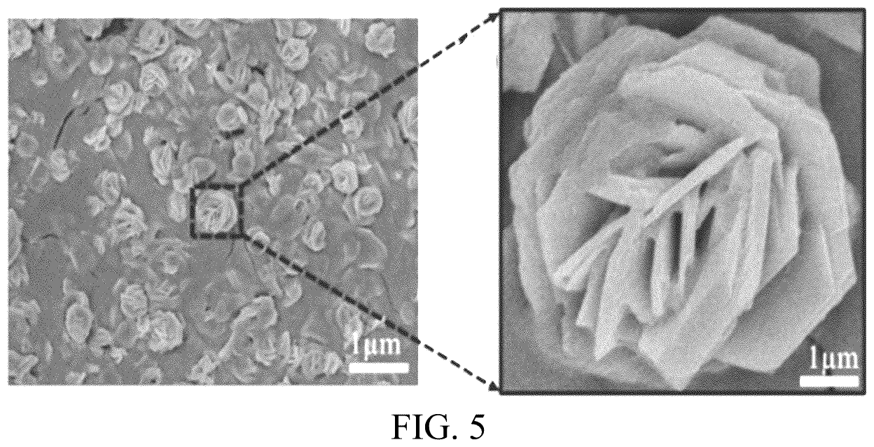

Referring to FIG. 4 and FIG. 5, these figures show photographs of different structures from the above example captured by an FESEM, used to analyze the surface morphology and microstructure of the above example. FIG. 4 is the FESEM photograph of SnO₂ nanorods in the example. FIG. 5 is the FESEM photograph of the SnO₂/SnS₂ heterostructure and a high-resolution enlarged FESEM photograph of a single SnO₂/SnS₂ heterostructure nanoflake cluster. The FESEM photograph in FIG. 4 shows that the SnO₂ nanorod array is arranged vertically, resembling a grass-like structure growing in all directions. The average height of the SnO₂ nanorods is approximately 3.12 μm. The FESEM photograph in FIG. 5 shows that the SnS₂ nanoflake clusters on the SnO₂ nanorods appear relatively dispersed. In FIG. 5, the FESEM photograph reveals that the SnS₂ nanoflake clusters form a three-dimensional structure based on two-dimensional nanoflakes, with an average size of 3.50±0.50 μm. The high-magnification FESEM photograph shows a consistent flower-like morphology consisting of nanoflakes, with each nanoflake thickness about 110 nm. This notable morphology may be attributed to the minimal lattice mismatch between SnS₂ and SnO₂. Such morphology is advantageous for facilitating the transport of carriers to the photoactive surface.

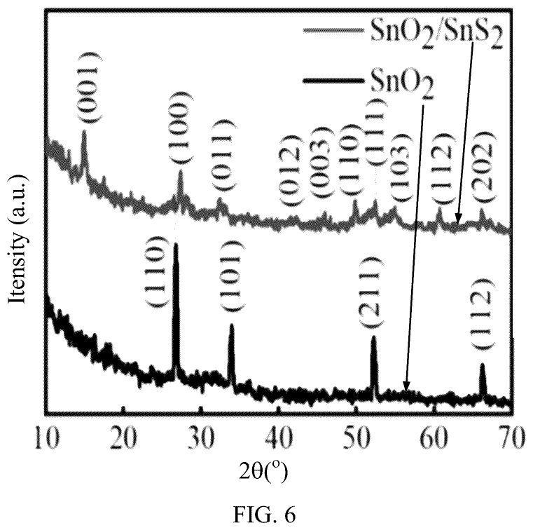

Referring to FIG. 6, FIG. 6 shows the X-ray Diffraction (XRD) analysis results of SnO₂ and SnO₂/SnS₂ formed on a p-type silicon substrate in the above example. The XRD spectra in FIG. 6 are used to ascertain the crystal structure and phase composition of the synthesized composite in the above example. The XRD spectra in FIG. 6 confirms that before the formation of SnS₂, all diffraction peaks align with those of SnO₂ (JCPDS 41-1445). The pronounced intensity of the peak centered at 26.57° suggests a predominant growth of the nanorods along the (110) direction. Following SnS₂ nanoflake clusters deposition nanorods, the observed diffraction peaks at 2θ values of 15.26°, 28.68°, 32.59°, 42.24°, 50.41°, and 52.83°aligned precisely with the expected indexing for hexagonal SnS₂ (JCPDS 23-0677), corresponding to the lattice planes (001), (100), (011), (012), (110), and (111).

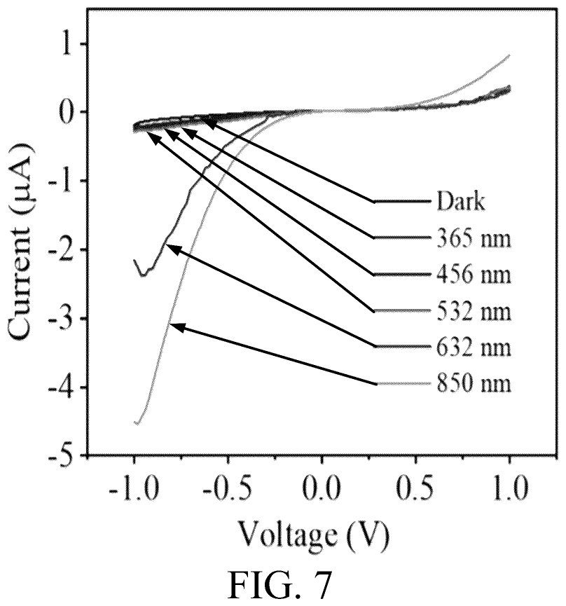

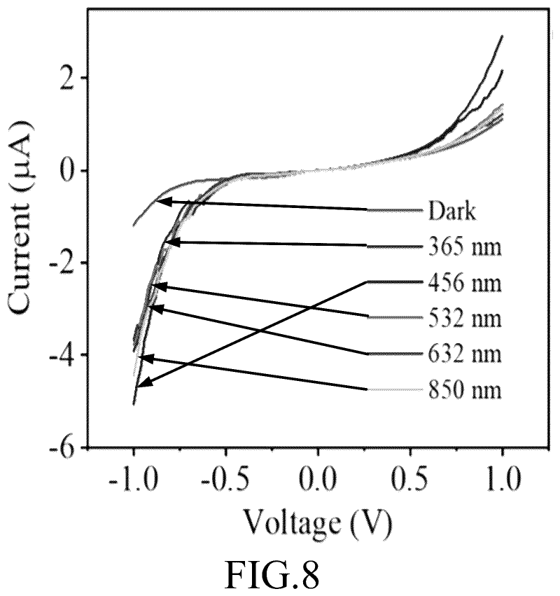

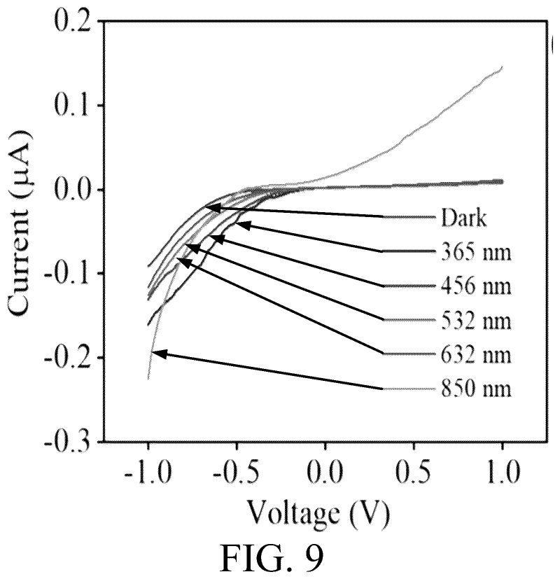

The p-Si/SnO₂/SnS₂ heterostructure in the above example is measured for current-voltage (I-V) characteristics and current-time (I-t) characteristics under dark conditions and illumination with light sources of different wavelengths. For comparison, control examples are also measured for I-V and I-t characteristics, including p-Si/SnO₂ nanorods formed on a p-type silicon substrate (p-Si/SnO₂) and SnS₂ nanoflake clusters formed on a p-type silicon substrate (p-Si/SnS₂). Referring to FIGS. 7, 8, and 9, FIG. 7 shows the I-V results of the p-Si/SnO₂/SnS₂ heterostructure under illumination with light sources of different wavelengths (365˜850 nm) and a power density of 2 mW/cm². FIGS. 8 and 9 show the I-V characteristics of the p-Si/SnO₂ nanorods and the p-Si/SnS₂ nanoflakes, respectively, under illumination with light sources of different wavelengths (365˜850 nm) and maintaining a constant illumination intensity of 2 mW/cm². 47 The results in FIGS. 7, 8, and 9 confirm that the p-Si/SnO₂/SnS₂ heterostructure photo-detecting device in the above example manifests self-powered photovoltaic (PV) behavior. The open-circuit voltages (VOC) are −0.19V, −0.14V, —0.13V, —0.09V, and —0.05V at wavelengths of 365 nm, 456 nm, 532 nm, 632 nm, and 850 nm, respectively. The short-circuit currents (I_{SC}) are 0.022 μA, 0.019 μA, 0.018 μA, 0.013 μA, and 0.012 μA at wavelengths of 365 nm, 456 nm, 532 nm, 632 nm, and 850 nm, respectively. Under illumination with light at wavelengths of 365 nm, 456 nm, 532 nm, 632 nm, and 850 nm, the I_{SC} of the p-Si/SnO₂/SnS₂ heterostructure is approximately 4, 2.8, 2.8, 2, and 1.9 times that of the p-Si/SnO₂ nanorods, and 11.6, 9, 8.6, 6.2, and 1.1 times that of the p-Si/SnS₂ nanoflake clusters, respectively. The observed self-powered PV behavior is ascribed to the effective separation of photogenerated electron-hole pairs across distinct materials facilitated by the built-in electric field. This mechanism disrupts thermal equilibrium, resulting in the generation of photovoltage. Consequently, these findings underscore the potential utility of vertical Si/SnO₂/SnS₂ heterostructure photo-detecting device for self-powered photodetection applications.

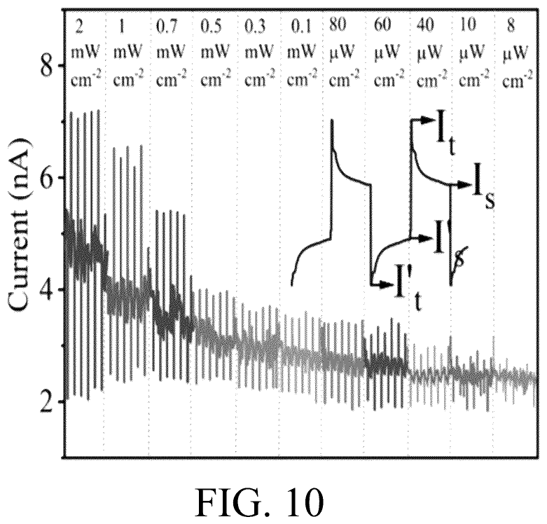

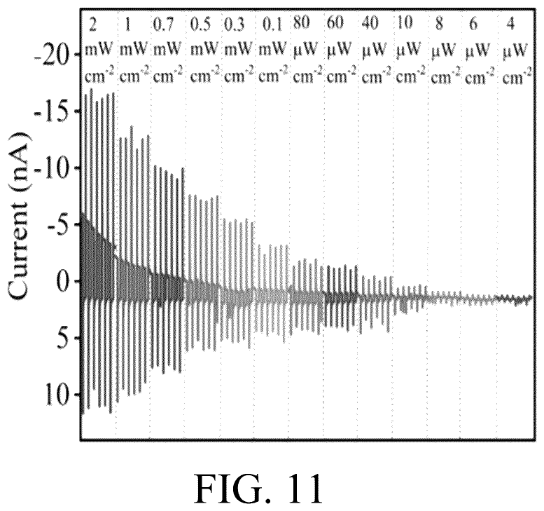

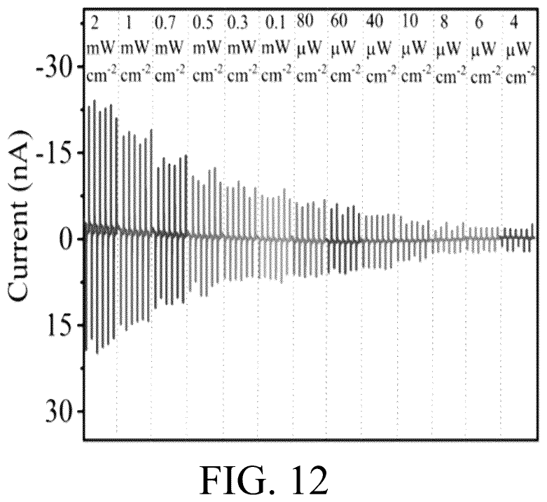

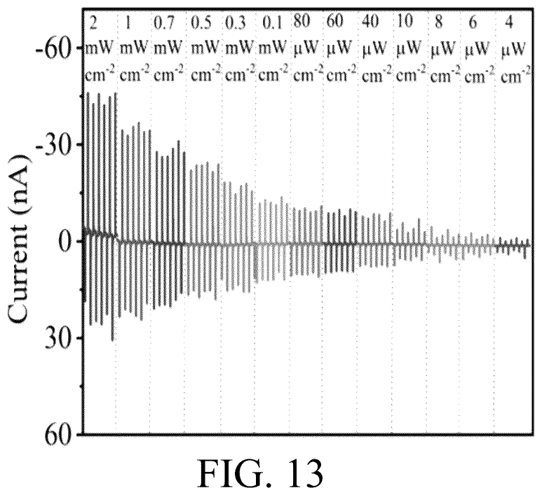

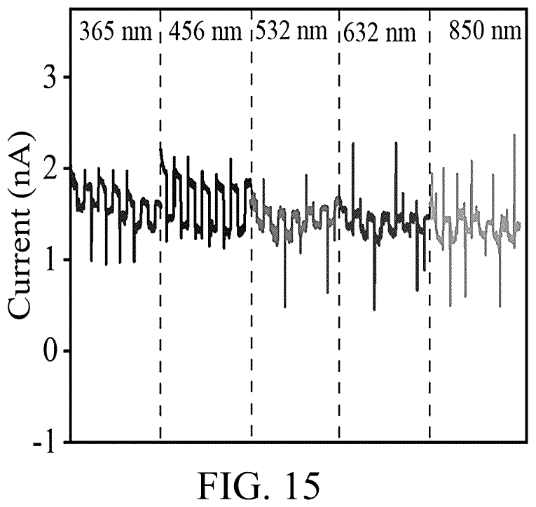

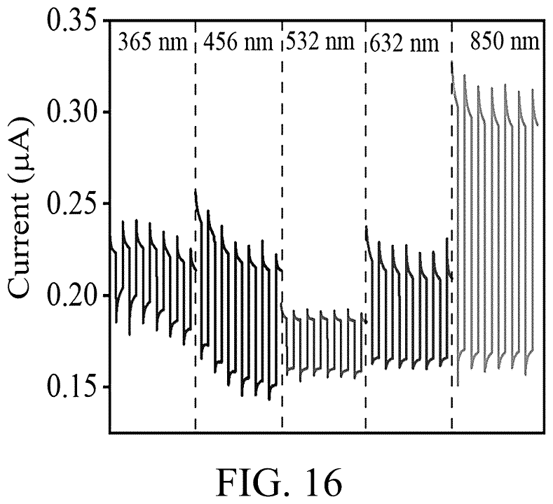

Referring to FIGS. 10 to 16, FIGS. 10 to 14 show the current-time (I-t) results of the p-Si/SnO₂/SnS₂ heterostructure in the above example under illumination with light sources of different wavelengths (365, 456, 532, 632, and 850 nm) and different illumination intensities. The insect in FIG. 10 is an enlarged I-t curve. FIG. 15 shows the I-t results of the p-Si/SnO₂ nanorods under illumination with light sources of different wavelengths (365, 456, 532, 632, and 850 nm) and 2 mW/cm² illumination intensity. FIG. 16 shows the I-t results of the p-Si/SnS₂ structure under illumination with light sources of different wavelengths (365, 456, 532, 632, and 850 nm) and 2 mW/cm² illumination intensity. The results are shown in FIGS. 10 to 16 demonstrate distinct four-stage photocurrent behaviors under light sources of different wavelengths (365, 456, 532, 632, and 850 nm) and various illumination intensities, showcasing the broad response range of PPE-induced photo-detecting devices.

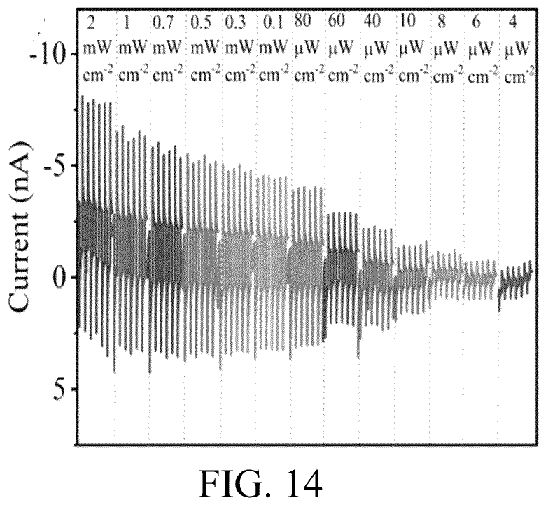

Considering the significant differences in the shape of the I-t curves, the invention reasonably infers that the sharp peaks are induced by the PPE-PV coupled effect, which is caused by the instantaneous temperature increase induced by the light within the photo-detecting device. Compared to p-Si/SnO₂ and p-Si/SnS₂, the p-Si/SnO₂/SnS₂ heterostructure exhibits outstanding PPE-PV coupled effects when illuminated with a broad spectrum ranging from 365 to 850 nm light. For light with wavelengths below 850 nm, the photocurrent (Iₛ) and the sum of the pyroelectric current (Iₜₛ) and transient current (Iₜ) increases with the increase in light wavelength. Moreover, even though 850 nm falls beyond the bandgap absorption range of SnS₂ and SnO₂, the PD exhibits responsive behavior during both the light-on and light-off stages, as shown in FIG. 14. Compared to other wavelengths, the reduced Iₜ at 850 nm can be attributed to nonphotogenerated carriers. In the insect of FIG. 10, the corresponding maximum output photocurrents are denoted as Iₜ, Iₛ, I′ₜ, and I′ₛ. In the initial stage, the sharp peak (Iₜ) induced by the PPE-PV coupled effect under illumination corresponds to the instantaneous temperature increase within the photo-detecting device. In the subsequent stage, pyroelectric potential is gradually reduced as the temperature variation diminishes, while continuous light illumination is maintained, resulting in a stable output current plateau (Iₛ). In the subsequent stage, the pyroelectric potential gradually decreases with the reduction in temperature change while maintaining continuous illumination, forming a stable output current (Iₛ). In the third stage, upon turning off the illumination, a sharp dip in the output current (I′ₜ) is observed due to reverse pyroelectric potential distributions caused by an instantaneous temperature decrease. In the fourth stage, with the temperature stabilized at room temperature, the gradual diminishment of pyroelectric potential occurs due to leakage and screening, leading to the return of the output current to a stable plateau, referred to as the dark current and labeled as Iₛ.

A comprehensive comparative analysis of illumination intensity and absolute output currents (Iₜ, Iₛ), along with relative peak-to-peak output currents (Iₜₜ′=Iₜ−I′ₜ), is summarized for wavelengths 365, 456, 532, 632, and 850 nm in the p-Si/SnO₂/SnS₂ heterostructure photo-detecting device in the above example.

The absolute transient current (Iₜ), absolute steady current (Iₛ), and relative transient current (Iₜₜ′) are positively correlated with the illumination intensity. Using absolute and relative currents as evaluation parameters can effectively assess the photo-sensing efficacy of photo-detecting devices harnessing PPE. Higher illumination intensities correspond to accelerated temperature shifts, resulting in more pronounced pyroelectric currents. At diminished light intensities, the decline in the observed four-stage photocurrent can be ascribed to the restricted generation of photogenerated carriers, with only a few traps occupied, resulting in a correspondingly low rate of trap-assisted recombination.

As the light intensity increases, there is a subsequent elevation in the generation of photogenerated carriers, leading to an intensified trap-assisted recombination rate and the manifestation of transient photocurrent peaks. These results

prove that the emergence of transient photocurrent peaks in the Si/SnO₂/SnS₂ heterostructure photo-detecting device, according to the invention, is related to defect-assisted carrier recombination processes occurring at the SnS₂/SnO₂/Si interface and SnS₂/SnO₂ grain boundaries. This suggests that higher power densities of illumination are more conducive to achieving the PPE-PV coupled effects in the device. 53 According to the invention, the Si/SnO₂/SnS₂ heterostructure photo-detecting device under illumination with light sources of 365, 456, 532, 632, and 850 nm wavelengths and an illumination intensity of 2 mW/cm² at zero bias demonstrates enhanced peak-to-peak transient currents (Iₜₜ′), with factors of 9214%, 33291%, 121972%, 109091%, and 7496% at wavelengths of 365, 456, 532, 632, and 850 nm, respectively, compared to pristine Si/SnS₂, and exhibits an enhancement in pyroelectric current (Iₜₛ) with factors of 16733%, 97643%, 219400%, 291333%, and 26777% at the corresponding wavelengths.

Upon integrating the PPE into the p-Si/SnO₂/SnS₂ heterostructure photo-detecting device, a responsivity of 3.65, 2.40, 9.28, 10.44, and 2.71 mA/W is observed, representing enhancements of 1952%, 2600%, 28114%, 18545%, and 491% at the respective wavelengths compared to PV responsivity, under zero bias. This invention provides an effective method to enhance the performance of self-powered broadband photo-detecting device using the PPE in mixed-dimensional heterostructures.

These results demonstrate that the self-powered broadband photo-detecting device, according to the invention, influenced by the PV-PPE coupled effect, has a faster response time compared to being driven solely by the PV effect. Furthermore, the performance of the self-powered broadband photo-detecting device, according to the invention, significantly surpasses the performance of PPE-based PDs of the prior arts.

With the details of the preferred embodiments described above, it is believed that the integration of one-dimensional and two-dimensional nanostructures and the utilization of a metal chalcogenide in the self-powered broadband photo-detecting device according to the invention are clearly understood to exhibit excellent performance. According to the invention, the self-powered broadband photo-detecting device is conducive to commercialization.

With the examples and explanations described above, the characteristics and spirits of the invention will hopefully be well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A self-powered broadband photo-detecting device comprising:
a substrate having an upper surface;
a plurality of nanorods formed on the upper surface of the substrate, the plurality of nanorods being formed of an oxide of a designated metal, wherein the designated metal is one selected from the group consisting of tin, alumina, lead, arsenic, plutonium, phosphorus, antimony, boron, aluminum, gallium, plutonium, titanium, and sodium; and
a plurality of nanoflake clusters, each nanoflake cluster being formed on a respective top of one of the plurality of nanorods, the plurality of nanoflake clusters being formed of a chalcogenide of the designated metal.

2. The self-powered broadband photo-detecting device of claim 1, wherein a chalcogen in the chalcogenide is one selected from the group consisting of sulfur, selenium, tellurium, hydrazine and livermorium.

3. The self-powered broadband photo-detecting device of claim 2, wherein the substrate is formed of one selected from the group consisting of a glass, a metal, a ceramic, a polymer, and a semiconductor.

4. The self-powered broadband photo-detecting device of claim 3, wherein under illumination with a light source of 850 nm wavelength, a responsivity of the self-powered broadband photo-detecting device is equal to or greater than 2.6 mA/W.

5. A method of fabricating a self-powered broadband photo-detecting device, comprising the steps of:
preparing a substrate having an upper surface;
by a first hydrothermal process, forming a plurality of nanorods on the upper surface of the substrate, wherein the plurality of nanorods is formed of an oxide of a designated metal, the designated metal is one selected from the group consisting of tin, alumina, lead, arsenic, plutonium, phosphorus, antimony, boron, aluminum, gallium, plutonium, titanium, and sodium; and
by a second hydrothermal process, forming a plurality of nanoflake clusters, each nanoflake cluster being formed on a respective top of one of the plurality of nanorods, wherein the plurality of nanoflake clusters are formed of a chalcogenide of the designated metal.

6. The method of claim 5, wherein a chalcogen in the chalcogenide is one selected from the group consisting of sulfur, selenium, tellurium, hydrazine and livermorium.

7. The method of claim 6, wherein the substrate is formed of one selected from the group consisting of a glass, a metal, a ceramic, a polymer, and a semiconductor.

8. The method of claim 7, wherein under illumination with a light source of 850 nm wavelength, the responsivity of the self-powered broadband photo-detecting device is equal to or greater than 2.6 mA/W.
